(19) United States
(12) Patent Application Publication
(10) Pub. No.: US 2011/0241175 A1
(43) Pub. Date: Oct. 6, 2011

(54) HARDMASK COMPOSITION FOR FORMING RESIST UNDERLAYER FILM, PROCESS FOR PRODUCING A SEMICONDUCTOR INTEGRATED CIRCUIT DEVICE, AND SEMICONDUCTOR INTEGRATED CIRCUIT DEVICE

(76) Inventors: Sang Ran KOH, Uiwang (KR); Sang Kyun KIM, Uiwang (KR); Sang Hak LIM, Uiwang (KR); Mi Young KIM, Uiwang (KR); Hui Chan YUN, Uiwang (KR); Do Hyeon KIM, Uiwang (KR); Dong Seon UH, Uiwang (KR); Jong Seob KIM, Uiwang (KR)

(21) Appl. No.: 13/160,544

(22) Filed: Jun. 15, 2011

Related U.S. Application Data
(63) Continuation of application No. PCT/KR2008/007895, filed on Dec. 31, 2008.

(30) Foreign Application Priority Data
Dec. 17, 2008 (KR) 10-2008-0128625

(51) Int. Cl. H01L 29/02; C08G 77/38; H01L 21/31

(52) U.S. Cl. 257/618; 525/477; 525/474; 438/703; 257/E21.24; 257/E29.002

(57) ABSTRACT

A hardmask composition for forming a resist underlayer film, a process for producing a semiconductor integrated circuit device, and a semiconductor integrated circuit device, the hardmask composition including an organosilane polymer, and a stabilizer, the stabilizer including one of acetic anhydride, methyl acetoacetate, propionic anhydride, ethyl-2-ethylacetoacetate, butyric anhydride, ethyl-2-ethylacetoacetate, valeric anhydride, 2-methylbutyric anhydride, nonanol, decanol, undecanol, dodecanol, propylene glycol propyl ether, propylene glycol ethyl ether, propylene glycol methyl ether, propylene glycol, phenyltrimethoxysilane, diphenylhexamethoxydisiloxane, diphenylhexaethoxydisiloxane, dioctyltetramethyldisiloxane, hexamethyltrisiloxane, tetramethyldisiloxane, decamethyltetrasiloxane, dodecamethylpentasiloxane, hexamethyldisiloxane, and mixtures thereof.

### CROSS-REFERENCE TO RELATED APPLICATION

This application is a continuation of pending International Application No. PCT/KR2008/007895, entitled “Hardmask Composition with Improved Storage Stability for Forming Resist Underlayer Film,” which was filed on Dec. 31, 2008, the entire contents of which are hereby incorporated by reference.

### BACKGROUND

1. Field

Embodiments relate to a hardmask composition for forming a resist under layer film, a process for producing a semiconductor integrated circuit device, and a semiconductor integrated circuit device.

2. Description of the Related Art

With decreasing width of lines used in semiconductor microcircuits, the use of photoresists with smaller thickness may be desirable due to aspect ratios of the patterns. However, if a photoresist is too thin, difficulty in performing a role as a mask in a subsequent pattern transfer (i.e. etching) process may occur. That is, the thin photoresist may be worn out during etching. Thus, an underlying substrate may not be etched to a desired depth. Accordingly, hardmask processes have been introduced. Hardmasks are materials featuring high etch selectivity.

### SUMMARY

Embodiments are directed to a hardmask composition for forming a resist under layer film, a process for producing a semiconductor integrated circuit device, and a semiconductor integrated circuit device.

The embodiments may be realized by providing a hardmask composition for forming a resist underlayer film, the hardmask composition including an organosilane polymer, and a stabilizer, the stabilizer including one of acetic anhydride, methyl acetoacetate, propionic anhydride, ethyl-2-ethylacetoacetate, butyric anhydride, ethyl-2-ethylacetoacetate, valeric anhydride, 2-methylbutyric anhydride, nonanol, decanol, undecanol, dodecanol, propylene glycol propyl ether, propylene glycol ethyl ether, propylene glycol methyl ether, propylene glycol, phenyltrimethoxysilane, diphenylhexamethoxydisiloxane, diphenylhexaethoxydisiloxane, dioctyltetramethyldisiloxane, hexamethyltrisiloxane, tetramethyldisiloxane, decamethyltetrasiloxane, dodecamethylpentasiloxane, hexamethyldisiloxane, and mixtures thereof.

The organosilane polymer may be a polycondensate of hydrolysates of compounds represented by Formulae 1 and 2:

[R₁O]₃SiAr (1)

wherein, in Formula 1, Ar may be a C₆-C₃₀ functional group containing at least one substituted or unsubstituted aromatic ring and R₁ may be a C₁-C₆ alkyl group; and

[R₁O]₃Si R₂ (2)

wherein, in Formula 2, R₁ may be a C₁-C₆ alkyl group and R₂ may be a C₁-C₆ alkyl group or a hydrogen atom.

The organosilane polymer may be a polycondensate of hydrolysates of compounds represented by Formulae 1, 2 and 3:

[R₁O]₃SiAr (1)

wherein, in Formula 1, Ar may be a C₆-C₃₀ functional group containing at least one substituted or unsubstituted aromatic ring and R₁ may be a C₁-C₆ alkyl group; and

[R₁O]₃Si—R₂ (2)

wherein, in Formula 2, R₁ may be a C₁-C₆ alkyl group and R₂ may be a C₁-C₆ alkyl group or a hydrogen atom; and

[R₄O]₃Si—Y—Si[OR₅]₃ (3)

wherein, in Formula 3, R₄ and R₅ may each independently be a C₁-C₆ alkyl group, and Y may be a linking group including one of an aromatic ring, a substituted or unsubstituted linear or branched C₁-C₂₀ alkylene group, a C₁-C₂₀ alkylene group containing at least one aromatic or heterocyclic ring or having at least one urea or isocyanurate group in a backbone thereof, and a C₂-C₂₀ hydrocarbon group containing at least one multiple bond.

The organosilane polymer may be a polycondensate of hydrolysates of compounds represented by Formulae 1, 2 and 4:

[R₁O]₃SiAr (1)

wherein, in Formula 1, Ar may be a C₆-C₃₀ functional group containing at least one substituted or unsubstituted aromatic ring and R₁ may be a C₁-C₆ alkyl group; and

[R₁O]₃Si—R₂ (2)

wherein, in Formula 2, R₁ may be a C₁-C₆ alkyl group and R₂ may be a C₁-C₆ alkyl group or a hydrogen atom; and

[R₁O]₄Si (4)

wherein, in Formula 4, R₁ may be a C₁-C₆ alkyl group.

The organosilane polymer may be a polycondensate of hydrolysates of compounds represented by Formulae 1, 2, 3 and 4:

[R₁O]₃SiAr (1)

wherein, in Formula 1, Ar may be a C₆-C₃₀ functional group containing at least one substituted or unsubstituted aromatic ring and R₁ may be a C₁-C₆ alkyl group; and

[R₁O]3Si—R₂ (2)

wherein, in Formula 2, R₁ may be a C₁-C₆ alkyl group and R₂ may be a C₁-C₆ alkyl group or a hydrogen atom;

[R₄O]₃Si—Y—Si[OR₅]₃ (3)

wherein, in Formula 3, R₄ and R₅ may each independently be a C₁-C₆ alkyl group, and Y may be a linking group including one of an aromatic ring, a substituted or unsubstituted linear or branched C₁-C₂₀ alkylene group, a C₁-C₂₀ alkylene group containing at least one aromatic or heterocyclic ring or having at least one urea or isocyanurate group in a backbone thereof, and a C₂-C₂₀ hydrocarbon group containing at least one multiple bond; and

[R₁O]₄Si (4)

wherein, in Formula 4, R₁ may be a C₁-C₆ alkyl group.

The organosilane polymer may be a polycondensate of hydrolysates of compounds represented by Formulae 1, 3 and 4:

[R₁O]₃SiAr (1)

wherein, in Formula 1, Ar may be a C₆-C₃₀ functional group containing at least one substituted or unsubstituted aromatic ring and R₁ may be a C₁-C₆ alkyl group; and

[R₄O]₃Si—Y—Si[OR₅]₃ (3)

wherein, in Formula 3, R₄ and R₅ may each independently be a C₁-C₆ alkyl group, and Y may be a linking group including one of an aromatic ring, a substituted or unsubstituted linear or branched C₁-C₂₀ alkylene group, a C₁-C₂₀ alkylene group containing at least one aromatic or heterocyclic ring or having at least one urea or isocyanurate group in a backbone thereof, and a C₂-C₂₀ hydrocarbon group containing at least one multiple bond; and

[R₁O]₄Si (4)

wherein, in Formula 4, R₁ may be a C₁-C₆ alkyl group.

The hardmask composition may further include a compound including one of pyridinium p-toluenesulfonate, amidosulfobetain-16, (−)-camphor-10-sulfonic acid ammonium salt, ammonium formate, triethylammonium formate, trimethylammonium formate, tetramethylammonium formate, pyridinium formate, tetrabutylammonium formate, tetramethylammonium nitrate, tetrabutylammonium nitrate, tetrabutylammonium acetate, tetrabutylammonium azide, tetrabutylammonium benzoate, tetrabutylammonium bisulfate, tetrabutylammonium bromide, tetrabutylammonium chloride, tetrabutylammonium cyanide, tetrabutylammonium fluoride, tetrabutylammonium iodide, tetrabutylammonium sulfate, tetrabutylammonium nitrate, tetrabutylammonium nitrite, tetrabutylammonium p-toluenesulfonate, tetrabutylammonium phosphate, and mixtures thereof.

The stabilizer may include one of acetic anhydride, propylene glycol propyl ether, phenyltrimethoxysilane, hexamethyldisiloxane, dodecanol, and mixtures thereof.

The stabilizer may be present in an amount of about 1 to about 30 parts by weight, based on 100 parts by weight of the organosilane polymer.

The embodiments may also be realized by providing a process for producing a semiconductor integrated circuit device, the process including forming a carbon-based hardmask layer on a substrate, coating a hardmask composition on the carbon-based hardmask layer to form a silicon-based hardmask layer, forming a photoresist layer on the silicon-based hardmask layer, exposing portions of the photoresist layer to light through a mask to form a pattern, selectively removing exposed portions of the photoresist layer to form a patterned photoresist layer, transferring the pattern to the silicon-based hardmask layer using the patterned photoresist layer as an etch mask to form a patterned silicon-based hardmask layer, transferring the pattern to the carbon-based hardmask layer using the patterned silicon-based hardmask layer as an etch mask to form a patterned carbon-based hardmask layer, and transferring the pattern to the substrate using the patterned carbon-based hardmask layer as an etch mask, wherein the hardmask composition includes an organosilane polymer, and a stabilizer, the stabilizer including one of acetic anhydride, methyl acetoacetate, propionic anhydride, ethyl-2-ethylacetoacetate, butyric anhydride, ethyl-2-ethylacetoacetate, valeric anhydride, 2-methylbutyric anhydride, nonanol, decanol, undecanol, dodecanol, propylene glycol propyl ether, propylene glycol ethyl ether, propylene glycol methyl ether, propylene glycol, phenyltrimethoxysilane, diphenylhexamethoxydisiloxane, diphenylhexaethoxydisiloxane, dioctyltetramethyldisiloxane, hexamethyltrisiloxane, tetramethyldisiloxane, decamethyltetrasiloxane, dodecamethylpentasiloxane, hexamethyldisiloxane, and mixtures thereof.

The method may further include forming an antireflective coating on the silicon-based hardmask layer prior to forming the photoresist layer on the silicon-based hardmask layer.

The embodiments may also be realized by providing a semiconductor integrated circuit device prepared according to the method of an embodiment.

### BRIEF DESCRIPTION OF THE DRAWING

The embodiments will become more apparent to those of ordinary skill in the art by describing in detail exemplary embodiments with reference to the attached drawing, in which:

FIG. 1 illustrates a schematic cross-sectional view of a multilayer film including a carbon-based hardmask, a silicon-based hardmask, and a resist on a substrate.

### DETAILED DESCRIPTION

Korean Patent Application No. 10-2008-0128625, filed on Dec. 17, 2008, in the Korean Intellectual Property Office, and entitled: “Hardmask Composition with Improved Storage Stability for Forming Resist Underlayer Film,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. Like reference numerals refer to like elements throughout.

The embodiments provide a hardmask composition for forming a resist underlayer film. The hardmask composition may include (A) an organosilane polymer and (B) at least one stabilizer.

(A) Organosilane Polymer

Organosilane polymers for use in the hardmask composition of the embodiments may include, but are not limited to, the following polymers.

In an embodiment, the organosilane polymer (A) may be a polycondensate of hydrolysates of compounds represented by Formulae 1 and 2, below.

[R₁O]₃SiAr (1)

In Formula 1, Ar may be a C₆-C₃₀ functional group containing at least one substituted or unsubstituted aromatic ring and R₁ may be a C₁-C₆ alkyl group.

[R₁O]₃Si—R₂ (2)

In Formula 2, R₁ may be a C₁-C₆ alkyl group and R₂ may be a C₁-C₆ alkyl group or a hydrogen atom.

In another embodiment, the organosilane polymer (A) may be a polycondensate of hydrolysates of compounds represented by Formulae 1, 2, and 3, below.

[R₁O]₃SiAr (1)

In Formula 1, Ar may be a C₆-C₃₀ functional group containing at least one substituted or unsubstituted aromatic ring and R₁ may be a C₁-C₆ alkyl group.

[R₁O]3Si—R₂ (2)

In Formula 2, R₁ may be a C₁-C₆ alkyl group and R₂ may be a C₁-C₆ alkyl group or a hydrogen atom.

[R₄O]₃Si—Y—Si[OR₅]₃ (3)

In Formula 3, R₄ and R₅ may each independently be a C₁-C₆ alkyl group, and Y may be a linking group including one of an aromatic ring, a substituted or unsubstituted linear or branched C₁-C₂₀ alkylene group, a C₁-C₂₀ alkylene group containing at least one aromatic or heterocyclic ring or having at least one urea or isocyanurate group in a backbone thereof, and a C₂-C₂₀ hydrocarbon group containing at least one multiple bond.

In yet another embodiment, the organosilane polymer (A) may be a polycondensate of hydrolysates of compounds represented by Formulae 1, 2, and 4, below.

[R₁O]₃SiAr (1)

In Formula 1, Ar may be a C₆-C₃₀ functional group containing at least one substituted or unsubstituted aromatic ring and R₁ may be a C₁-C₆ alkyl group.

[R₁O]₃Si—R₂ (2)

In Formula 2, R₁ may be a C₁-C₆ alkyl group and R₂ may be a C₁-C₆ alkyl group or a hydrogen atom.

[R₁O]₄Si (4)

In Formula 4, R₁ may be a C₁-C₆ alkyl group.

In still another embodiment, the organosilane polymer (A) may be a polycondensate of hydrolysates of compounds represented by Formulae 1, 2, 3, and 4, below.

[R₁O]₃SiAr (1)

In Formula 1, Ar may be a C₆-C₃₀ functional group containing at least one substituted or unsubstituted aromatic ring and R₁ may be a C₁-C₆ alkyl group.

[R₁O]₃Si—R₂ (2)

In Formula 2, R₁ may be a C₁-C₆ alkyl group and R₂ may be a C₁-C₆ alkyl group or a hydrogen atom.

[R₄O]₃Si—Y—Si[OR₅]₃ (3)

In Formula 3, R₄ and R₅ may each independently be a C₁-C₆ alkyl group, and

Y may be a linking group including one of an aromatic ring, a substituted or unsubstituted linear or branched C₁-C₂₀ alkylene group, a C₁-C₂₀ alkylene group containing at least one aromatic or heterocyclic ring or having at least one urea or isocyanurate group in a backbone thereof, and a C₂-C₂₀ hydrocarbon group containing at least one multiple bond.

[R₁O]₄Si (4)

In Formula 4, R₁ may be a C₁-C₆ alkyl group.

In still another embodiment, the organosilane polymer (A) may be a polycondensate of hydrolysates of compounds represented by Formulae 1, 3, and 4, below.

[R₁O]₃SiAr (1)

In Formula 1, Ar may be a C₆-C₃₀ functional group containing at least one substituted or unsubstituted aromatic ring and R₁ may be a C₁-C₆ alkyl group.

[R₄O]₃Si—Y—Si[OR₅]₃ (3)

In Formula 3, R₄ and R₅ may each independently be a C₁-C₆ alkyl group, and

Y may be a linking group including one of an aromatic ring, a substituted or unsubstituted linear or branched C₁-C₂₀ alkylene group, a C₁-C₂₀ alkylene group containing at least one aromatic or heterocyclic ring or having at least one urea or isocyanurate group in a backbone thereof, and a C₂-C₂₀ hydrocarbon group containing at least one multiple bond.

[R₁O]₄Si (4)

In Formula 4, R₁ may be a C₁-C₆ alkyl group.

The hydrolysis and polycondensation reactions for preparation of the organosilane polymer (A) may preferably be carried out in the presence of an acid catalyst.

The acid catalyst may include one of inorganic acids, e.g., nitric acid, sulfuric acid, and hydrochloric acid; alkyl esters of organic sulfonic acids, e.g., p-toluenesulfonic acid monohydrate and diethyl sulfate; and mixtures thereof.

The hydrolysis and/or condensation reaction may be suitably controlled by varying the kind, the amount, and the addition mode of the acid catalyst. The acid catalyst may be used in an amount of about 0.001 to about 5 parts by weight, based on 100 parts by weight of the compounds participating in the hydrolysis. Maintaining the amount of the acid catalyst in an amount of about 0.001 parts by weight or greater may help ensure that reaction rates are not remarkably slowed. Maintaining the amount of the acid catalyst at about 5 parts by weight or less may help prevent an excessive increase in the reaction rates, thereby helping ensure preparation of a polycondensation product having a desired molecular weight.

In an implementation, some alkoxy groups of the compounds participating in the hydrolysis may remain unchanged without being converted to hydroxyl groups after the hydrolysis. In another implementation, some of the alkoxy groups may also remain in the final polycondensate.

The organosilane polymer (A) is preferably present in an amount of about 1 to about 50 parts by weight, and more preferably about 1 to about 30 parts by weight, based on 100 parts by weight of the hardmask composition. Maintaining the amount of the organosilane polymer within this range may help ensure that the hardmask composition exhibits excellent characteristics, e.g., good coatability.

(B) Stabilizer

The stabilizer (B) may include one of acetic anhydride, methyl acetoacetate, propionic anhydride, ethyl-2-ethylacetoacetate, butyric anhydride, ethyl-2-ethylacetoacetate, valeric anhydride, 2-methylbutyric anhydride, nonanol, decanol, undecanol, dodecanol, propylene glycol propyl ether, propylene glycol ethyl ether, propylene glycol methyl ether, propylene glycol, phenyltrimethoxysilane, diphenylhexamethoxydisiloxane, diphenylhexaethoxydisiloxane, dioctyltetramethyldisiloxane, hexamethyltrisiloxane, tetramethyldisiloxane, decamethyltetrasiloxane, dodecamethylpentasiloxane, hexamethyldisiloxane, and mixtures thereof.

The stabilizer may play a role in blocking labile functional groups of the organosilane polymer with weak bonds to contribute to an improvement in the storage stability of the hardmask composition.

The stabilizer is preferably present in an amount of about I to about 30 parts by weight, based on 100 parts by weight of the organosilane polymer (A). Maintaining the amount of the stabilizer at about 1 to about 30 parts by weight may help ensure that the hardmask composition exhibits improved storage stability. The amount of the stabilizer used may be dependent on the kinds of the stabilizer and the organosilane polymer.

The hardmask composition of an embodiment may further include a crosslinking catalyst including one of sulfonic acid salts of organic bases, e.g., pyridinium p-toluenesulfonate, amidosulfobetain-16, and (−)-camphor-10-sulfonic acid ammonium salt; formates, e.g., ammonium formate, triethylammonium formate, trimethylammonium formate, tetramethylammonium formate, pyridinium formate, and tetrabutylammonium formate; tetramethylammonium nitrate; tetrabutylammonium nitrate; tetrabutylammonium acetate; tetrabutylammonium azide; tetrabutylammonium benzoate; tetrabutylammonium bisulfate; tetrabutylammonium bromide; tetrabutylammonium chloride; tetrabutylammonium cyanide; tetrabutylammonium fluoride; tetrabutylammonium iodide; tetrabutylammonium sulfate; tetrabutylammonium nitrate; tetrabutylammonium nitrite; tetrabutylammonium p-toluenesulfonate; tetrabutylammonium phosphate, and mixtures thereof.

The crosslinking catalyst may promote crosslinking of the organosilane polymer (A) to advantageously improve etch resistance and solvent resistance of the hardmask.

The crosslinking catalyst is preferably present in an amount of about 0.0001 to about 0.01 parts by weight, based on 100 parts by weight of the organosilane polymer (A). Maintaining the amount of the crosslinking catalyst at about 0.0001 to about 0.01 parts by weight may help ensure that the hardmask composition exhibits improved etch resistance and solvent resistance without a deterioration in storage stability.

In an implementation, the hardmask composition may further include an additive including one of crosslinkers, radical stabilizers, and surfactants.

The hardmask composition of an embodiment may further include a solvent.

Examples of solvents suitable for use in the hardmask composition of an embodiment may include acetone, tetrahydrofuran, benzene, toluene, diethyl ether, chloroform, dichloromethane, ethyl acetate, propylene glycol methyl ether, propylene glycol ethyl ether, propylene glycol propyl ether, propylene glycol methyl ether acetate (PGMEA), propylene glycol ethyl ether acetate, propylene glycol propyl ether acetate, ethyl lactate, γ-butyrolactone, and methyl isobutyl ketone (MIBK) These solvents may be used alone or as a mixture of two or more thereof. In an implementation, the solvent used may be different from the stabilizer.

The solvent is preferably present in an amount of about 70 to about 99.9% by weight, and more preferably about 85 to about 99% by weight, based on a total weight of the composition.

The embodiments also provide a process for producing a semiconductor integrated circuit device using the hardmask composition. For example, the process may include (a) forming a carbon-based hardmask layer on a substrate, (b) coating the hardmask composition of an embodiment on the carbon-based hardmask layer to form a silicon-based hardmask layer, (c) forming a photoresist layer on the silicon-based hardmask layer, (d) exposing portions of the photoresist layer to light from a suitable light source through a mask to form a pattern, (e) selectively removing the exposed portions of the photoresist layer, (f) transferring the pattern to the silicon-based hardmask layer using the patterned photoresist layer as an etch mask, (g) transferring the pattern to the carbon-based hardmask layer using the patterned silicon-based hardmask layer as an etch mask, and (h) transferring the pattern to the substrate using the patterned carbon-based hardmask layer as an etch mask.

If desired, the process may further include forming an antireflective coating on the silicon-based hardmask layer prior to step (c).

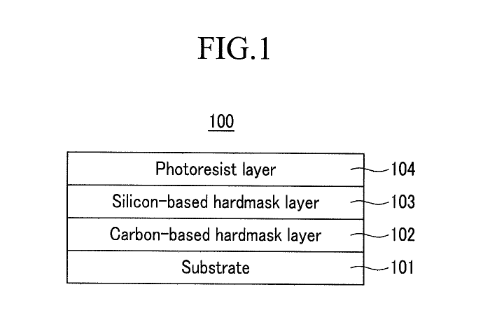

FIG. 1 illustrates a schematic cross-sectional view of a multilayer film 100 including a carbon-based hardmask layer 102, a silicon-based hardmask layer 103, and a photoresist layer 104 on a substrate 101, e.g., a structure formed by the process of step (c), above.

The embodiments also provide a semiconductor integrated circuit device produced using the process.

The following Examples and Comparative Examples are provided in order to set forth particular details of one or more embodiments. However, it will be understood that the embodiments are not limited to the particular details described. Further, the Comparative Examples are set forth to highlight certain characteristics of certain embodiments, and are not to be construed as either limiting the scope of the invention as exemplified in the Examples or as necessarily being outside the scope of the invention in every respect.

### EXAMPLES

### Comparative Example 1

1,750 g of methyltrimethoxysilane, 340 g of phenyltrimethoxysilane, and 313 g of trimethoxysilane were dissolved in 5,600 g of propylene glycol monomethyl ether acetate (PGMEA) in a 10-liter four-neck flask equipped with a mechanical agitator, a condenser, a dropping funnel, and a nitrogen inlet tube. To the solution was added 925 g of an aqueous nitric acid solution (1,000 ppm). After the mixture was allowed to react at 60° C. for 1 hour, methanol was removed from the reaction mixture under reduced pressure. The reaction was continued for 1 week while maintaining the reaction temperature at 50° C. After completion of the reaction, hexane was added to the reaction mixture to precipitate a polymer.

2.0 g of the polymer was diluted with 100 g of methyl isobutyl ketone

(MIBK), and 0.002 g of pyridinium p-toluenesulfonate was added thereto. A portion of the resulting solution was spin-coated on a silicon wafer coated with silicon nitride and a carbon-based hardmask, followed by baking at 240° C. for 60 seconds to form a 500 Å thick film.

### Comparative Example 2

49.3 g of methyltrimethoxysilane, 43.9 g of phenyltrimethoxysilane, and 306.8 g of 1,2-bis(triethoxysilyl)ethane were dissolved in 1,600 g of propylene glycol monomethyl ether acetate (PGMEA) in a 3-liter four-neck flask equipped with a mechanical agitator, a condenser, a dropping funnel, and a nitrogen inlet tube. To the solution was added 131.3 g of an aqueous nitric acid solution (1,000 ppm). After the mixture was allowed to react at room temperature for 1 hour, alcohols were removed from the reaction mixture under reduced pressure. The reaction was continued for 1 week while maintaining the reaction temperature at 50° C. After completion of the reaction, hexane was added to the reaction mixture to precipitate a polymer.

2.0 g of the polymer was diluted with 100 g of MIBK, and 0.002 g of pyridinium p-toluenesulfonate was added thereto. A portion of the resulting solution was spin-coated on a silicon wafer coated with silicon nitride and a carbon-based hardmask, followed by baking at 240° C. for 60 seconds to form a 500 Å thick film.

### Comparative Example 3

220.1 g of methyltrimethoxysilane, 68.0 g of phenyltrimethoxysilane and 612.0 g of tetraethyl orthosilicate were dissolved in 2,100 g of propylene glycol monomethyl ether acetate (PGMEA) in a 5-liter four-neck flask equipped with a mechanical agitator, a condenser, a dropping funnel, and a nitrogen inlet tube. To the solution was added 222.3 g of an aqueous nitric acid solution (1,000 ppm). After the mixture was allowed to react at room temperature for 5 hours, alcohols were removed from the reaction mixture under reduced pressure. The reaction was continued for 1 week while maintaining the reaction temperature at 50° C. After completion of the reaction, hexane was added to the reaction mixture to precipitate a polymer.

2.0 g of the polymer was diluted with 100 g of MIBK, and 0.002 g of pyridinium p-toluenesulfonate was added thereto. A portion of the resulting solution was spin-coated on a silicon wafer coated with silicon nitride and a carbon-based hardmask, followed by baking at 240° C. for 60 seconds to form a 500 Å thick film.

### Comparative Example 4

119.4 g of phenyltrimethoxysilane, 478.9 g of tetraethyl orthosilicate, and 601.6 g of 1,2-bis(triethoxysilyl)ethane were dissolved in 4,800 g of propylene glycol monomethyl ether acetate (PGMEA) in a 10-liter four-neck flask equipped with a mechanical agitator, a condenser, a dropping funnel, and a nitrogen inlet tube. To the solution was added 954.3 g of an aqueous nitric acid solution (1,000 ppm). After the mixture was allowed to react at room temperature for 6 hours, alcohols were removed from the reaction mixture under reduced pressure. The reaction was continued for 1 week while maintaining the reaction temperature at 50° C. After completion of the reaction, hexane was added to the reaction mixture to precipitate a polymer.

2.0 g of the polymer was diluted with 100 g of MIBK, and 0.002 g of pyridinium p-toluenesulfonate was added thereto. A portion of the resulting solution was spin-coated on a silicon wafer coated with silicon nitride and a carbon-based hardmask, followed by baking at 240° C. for 60 seconds to form a 500 Å thick film.

### Comparative Example 5

128.3 g of phenyltrimethoxysilane, 257.2 g of tetraethyl orthosilicate, 168.2 g of methyltrimethoxysilane, and 646.3 g of 1,2-bis(triethoxysilyl)ethane were dissolved in 4,800 g of propylene glycol monomethyl ether acetate (PGMEA) in a 10-liter four-neck flask equipped with a mechanical agitator, a condenser, a dropping funnel, and a nitrogen inlet tube. To the solution was added 969.5 g of an aqueous nitric acid solution (1,000 ppm). After the mixture was allowed to react at room temperature for 6 hours, alcohols were removed from the reaction mixture under reduced pressure. The reaction was continued for 1 week while maintaining the reaction temperature at 50° C. After completion of the reaction, hexane was added to the reaction mixture to precipitate a polymer.

2.0 g of the polymer was diluted with 100 g of MIBK, and 0.002 g of pyridinium p-toluenesulfonate was added thereto. A portion of the resulting solution was spin-coated on a silicon wafer coated with silicon nitride and a carbon-based hardmask, followed by baking at 240° C. for 60 seconds to form a 500 Å thick film.

### Example 1

1,750 g of methyltrimethoxysilane, 340 g of phenyltrimethoxysilane, and 313 g of trimethoxysilane were dissolved in 5,600 g of propylene glycol monomethyl ether acetate (PGMEA) in a 10-liter four-neck flask equipped with a mechanical agitator, a condenser, a dropping funnel, and a nitrogen inlet tube. To the solution was added 925 g of an aqueous nitric acid solution (1,000 ppm). After the mixture was allowed to react at 60° C. for 1 hour, methanol was removed from the reaction mixture under reduced pressure. The reaction was continued for 1 week while maintaining the reaction temperature at 50° C. After completion of the reaction, hexane was added to the reaction mixture to precipitate a polymer.

2.0 g of the polymer was diluted with 100 g of MIBK, and 0.002 g of pyridinium p-toluenesulfonate and 0.02 g of acetic anhydride were added thereto. A portion of the resulting solution was spin-coated on a silicon wafer coated with silicon nitride and a carbon-based hardmask, followed by baking at 240° C. for 60 seconds to form a 500 Å thick film.

### Example 2

49.3 g of methyltrimethoxysilane, 43.9 g of phenyltrimethoxysilane, and 306.8 g of 1,2-bis(triethoxysilyl)ethane were dissolved in 1,600 g of propylene glycol monomethyl ether acetate (PGMEA) in a 3-liter four-neck flask equipped with a mechanical agitator, a condenser, a dropping funnel, and a nitrogen inlet tube. To the solution was added 131.3 g of an aqueous nitric acid solution (1,000 ppm). After the mixture was allowed to react at room temperature for 1 hour, alcohols were removed from the reaction mixture under reduced pressure. The reaction was continued for 1 week while maintaining the reaction temperature at 50° C. After completion of the reaction, hexane was added to the reaction mixture to precipitate a polymer.

2.0 g of the polymer was diluted with 100 g of MIBK, and 0.002 g of pyridinium p-toluenesulfonate and 10 g of propylene glycol propyl ether were added thereto. A portion of the resulting solution was spin-coated on a silicon wafer coated with silicon nitride and a carbon-based hardmask, followed by baking at 240° C. for 60 seconds to form a 500 A thick film.

### Example 3

220.1 g of methyltrimethoxysilane, 68.0 g of phenyltrimethoxysilane and 612.0 g of tetraethyl orthosilicate were dissolved in 2,100 g of propylene glycol monomethyl ether acetate (PGMEA) in a 5-liter four-neck flask equipped with a mechanical agitator, a condenser, a dropping funnel and a nitrogen inlet tube. To the solution was added 222.3 g of an aqueous nitric acid solution (1,000 ppm). After the mixture was allowed to react at room temperature for 5 hours, alcohols were removed from the reaction mixture under reduced pressure. The reaction was continued for 1 week while maintaining the reaction temperature at 50° C. After completion of the reaction, hexane was added to the reaction mixture to precipitate a polymer.

2.0 g of the polymer was diluted with 100 g of MIBK, and 0.002 g of pyridinium p-toluenesulfonate and 0.02 g of phenyltrimethoxysilane were added thereto. A portion of the resulting solution was spin-coated on a silicon wafer coated with silicon nitride and a carbon-based hardmask, followed by baking at 240° C. for 60 seconds to form a 500 Å thick film.

### Example 4

119.4 g of phenyltrimethoxysilane, 478.9 g of tetraethyl orthosilicate, and 601.6 g of 1,2-bis(triethoxysilyl)ethane were dissolved in 4,800 g of propylene glycol monomethyl ether acetate (PGMEA) in a 10-liter four-neck flask equipped with a mechanical agitator, a condenser, a dropping funnel, and a nitrogen inlet tube. To the solution was added 954.3 g of an aqueous nitric acid solution (1,000 ppm). After the mixture was allowed to react at room temperature for 6 hours, alcohols were removed from the reaction mixture under reduced pressure. The reaction was continued for 1 week while maintaining the reaction temperature at 50° C. After completion of the reaction, hexane was added to the reaction mixture to precipitate a polymer.

2.0 g of the polymer was diluted with 100 g of MIBK, and 0.002 g of pyridinium p-toluenesulfonate and 0.02 g of hexamethyldisiloxane were added thereto. A portion of the resulting solution was spin-coated on a silicon wafer coated with silicon nitride and a carbon-based hardmask, followed by baking at 240° C. for 60 seconds to form a 500 Å thick film.

### Example 5

128.3 g of phenyltrimethoxysilane, 257.2 g of tetraethyl orthosilicate, 168.2 g of methyltrimethoxysilane, and 646.3 g of 1,2-bis(triethoxysilyl)ethane were dissolved in 4,800 g of propylene glycol monomethyl ether acetate (PGMEA) in a 10-liter four-neck flask equipped with a mechanical agitator, a condenser, a dropping funnel and a nitrogen inlet tube. To the solution was added 969.5 g of an aqueous nitric acid solution (1,000 ppm). After the mixture was allowed to react at room temperature for 6 hours, alcohols were removed from the reaction mixture under reduced pressure. The reaction was continued for 1 week while maintaining the reaction temperature at 50° C. After completion of the reaction, hexane was added to the reaction mixture to precipitate a polymer.

2.0 g of the polymer was diluted with 100 g of MIBK, and 0.002 g of pyridinium p-toluenesulfonate and 0.2 g of dodecanol were added thereto. A portion of the resulting solution was spin-coated on a silicon wafer coated with silicon nitride and a carbon-based hardmask, followed by baking at 240° C. for 60 seconds to form a 500 Å thick film.

### Experimental Example 1

The solutions prepared in Comparative Examples 1-5 and Examples 1-5 were tested for stability. The solutions were stored at 40° C. for 30 and 60 days. States of the solutions (e.g., molecular weights of the polymers contained therein) were observed; and thicknesses of films (formed using the stored solutions and according to the procedures used to form a 500 Å thick film described in the Examples and Comparative Examples, above) after coating were measured. The results are shown in Table 1.

TABLE 1

| | | Before storage | | 30 days after storage | | 60 days after storage | |
|---|---|---|---|---|---|---|---|
| | | Normalized | | Normalized | | Normalized | |
| | Stabilizer | molecular | Thickness | molecular | Thickness | molecular | Thickness |
| Samples | (Amounts) | weight | (Å) | weight | (Å) | weight | (Å) |
| Comparative | — | 1.0 | 501 | 1.1 | 512 | Particles | Poor |
| Example 1 | | | | | | observed | coateing |
| Example 1 | Acetic anhydride | 1.0 | 500 | 1.0 | 501 | 1.0 | 499 |
| | (0.02 g) | | | | | | |
| Comparative | — | 1.0 | 499 | 1..0 | 501 | 1.1 | 513 |
| Example 2 | | | | | | | |
| Example 2 | Propylene glycol | 1.0 | 501 | 1.0 | 501 | 1.0 | 500 |
| | propyl ether | | | | | | |
| | (10 g) | | | | | | |
| Comparative | — | 1.0 | 502 | 1.1 | 517 | 1.2 | 530 |
| Example 3 | | | | | | | |
| Example 3 | Polytrimethoxy- | 1.0 | 501 | 1.0 | 501 | 1.0 | 502 |
| | silane | | | | | | |
| | (0.02 g) | | | | | | |
| Comparative | — | 1.0 | 500 | 1.2 | 535 | Particles | Poor |
| Example 4 | | | | | | observed | coating |
| Example 4 | Hexamethyldi- | 1.0 | 501 | 1.0 | 501 | 1.0 | 499 |
| | siloxane | | | | | | |
| | (0.02 g) | | | | | | |
| Comparative | — | 1.0 | 500 | 1.2 | 527 | Particles | Poor |
| Example 5 | | | | | | observed | coating |
| Example5 | Dodecanol (0.2 g) | 1.0 | 501 | 1.0 | 498 | 1.0 | 502 |

The normalized molecular weight refers to a value obtained by dividing the molecular weight of the corresponding polymer measured after the indicated time of storage by the molecular weight of the polymer measured immediately after the preparation of the polymer. The results in Table I show that the compositions of Examples 1-5 (each including the stabilizer) exhibited much better storage stability than the compositions of Comparative Examples 1-5 (each including no stabilizer).

### Experimental Example 2

An ArF photoresist was coated on each of the films formed in Examples 1-5, baked at 110° C. for 60 seconds, exposed to light using an ArF exposure system (ASML1250, FN70 5.0 active, NA 0.82), and developed with an aqueous solution of TMAH (2.38 wt %) to form an 80-nm line and space pattern. Exposure latitude (EL) margin of the pattern was measured as a function of exposure energy; and depth of focus (DoF) margin of the pattern was measured as a function of distance from a light source. The results are shown in Table 2.

TABLE 2

| Sample used | Pattern properties | |
|---|---|---|
| for film | EL (Δ mJ/exposure | DoF |
| formation | energy mJ) | (μm) |
| Example 1 | 0.08 | 0.21 |
| Example 2 | 0.11 | 0.24 |
| Example 3 | 0.18 | 0.22 |
| Example 4 | 0.22 | 0.19 |
| Example 5 | 0.20 | 0.21 |

The patterns all exhibited good photo profiles in terms of EL margin and DoF margin. The results in Table 2 demonstrate that the silicon-based spin-on hardmask compositions may be suitably used in semiconductor manufacturing processes.

### Experimental Example 3

The patterned specimens obtained in Experimental Example 2 were sequentially dry-etched with CFₓ plasma, O₂ plasma, and CFₓ plasma. The remaining organic materials were completely removed using O₂, and cross sections of the etched specimens were observed by FE-SEM. The results are shown in Table 3.

TABLE 3

| Sample used for | Pattern shape |
|---|---|
| film formation | after etching |
| Example 1 | Vertical |
| Example 2 | Vertical |
| Example 3 | Vertical |
| Example 4 | Vertical |
| Example 5 | Vertical |

The patterns all had vertical shapes after etching, indicating good etching characteristics of the specimens. The results reveal that the silicon-based spin-on hardmask compositions may suitably be used in semiconductor manufacturing processes.

By way of summation and review, a hardmask may include two layers. For example, a carbon-based hardmask and a silicon-based hardmask may be sequentially formed on a substrate, and a photoresist may be coated on the silicon-based hardmask. Although a thickness of the photoresist may be very small, a pattern of the thin photoresist may still be easily transferred to the silicon-based hardmask because of higher etch selectivity of the silicon-based hardmask for the photoresist than for the substrate. Etching of the carbon-based hardmask may be performed using the patterned silicon-based hardmask as a mask to transfer the pattern to the carbon-based hardmask. Finally, etching of the substrate may be performed using the patterned carbon-based hardmask as a mask to transfer the pattern to the substrate. Thus, the substrate may be etched to a desired thickness despite the use of the thin photoresist.

Hardmasks may be produced by chemical vapor deposition (CVD) in semiconductor manufacturing processes on an industrial scale. However, the formation of particles may be inevitable during CVD. Such particles may be embedded in the hardmasks, making the presence of the particles difficult to detect. The presence of particles may be insignificant in a pattern with a large line width. However, even a small number of particles may greatly affect electrical properties of a final device with decreasing line width, causing difficulties in the mass production of the device. Further, CVD may require a long time and expensive equipment to produce hardmasks.

Accordingly, the embodiments provide hardmask materials that can be applied by spin-on coating. Spin-on coating may be advantageous in that it may be easy to control the formation of particles, the processing time may be short, and existing coaters may be used, thereby incurring no substantial additional investment costs.

The silicon-based hardmask material according to an embodiment may have a sufficiently high silicon content in terms of etch selectivity. For example, silicon-based hardmask material according to an embodiment may not have a silicon content that is so high as to cause poor coatability and storage instability of the hardmask material. Too high or low a silicon content of the hardmask material is unsuitable for the mass production of hardmasks.

A general silane compound, in which three or more oxygen atoms are bonded to one silicon atom, may be sufficiently reactive to undergo uncontrollable condensation reactions even in the presence of a small amount of water without the use of an additional catalyst during hydrolysis. In addition, the highly reactive silane compound may be gelled during condensation or purification. Accordingly, it may be difficult to synthesize a polymer having satisfactory physical properties using the silane compound. Due to the instability of the polymer, it may be difficult to prepare a solution of the polymer that is stable during storage.

Accordingly, the embodiments provide a hardmask composition that can be applied by spin-on coating, a process for producing a semiconductor integrated circuit device using the hardmask composition, and a semiconductor integrated circuit produced using the process.

The embodiments provide a silicon-based hardmask composition with high etch selectivity and good storage stability.

The hardmask composition of the embodiments may exhibit excellent coating properties and may be very stable during storage. In addition, the hardmask composition of the embodiments may be used for the production of a hardmask with excellent characteristics. The hardmask may transfer a good pattern during lithography. Furthermore, the hardmask may have good etch resistance to plasma gas during subsequent etching for the formation of a pattern.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition for forming a resist underlayer film, the hardmask composition comprising
an organosilane polymer, and
a stabilizer, the stabilizer including one of acetic anhydride, methyl acetoacetate, propionic anhydride, ethyl-2-ethylacetoacetate, butyric anhydride, ethyl-2-ethylacetoacetate, valeric anhydride, 2-methylbutyric anhydride, nonanol, decanol, undecanol, dodecanol, propylene glycol propyl ether, propylene glycol ethyl ether, propylene glycol methyl ether, propylene glycol, phenyltrimethoxysilane, diphenylhexamethoxydisiloxane, diphenylhexaethoxydisiloxane, dioctyltetramethyldisiloxane, hexamethyltrisiloxane, tetramethyldisiloxane, decamethyltetrasiloxane, dodecamethylpentasiloxane, hexamethyldisiloxane, and mixtures thereof.

2. The hardmask composition as claimed in claim 1, wherein the organosilane polymer is a polycondensate of hydrolysates of compounds represented by Formulae 1 and 2:
[R₁O]₃SiAr (1)
wherein, in Formula I, Ar is a C₆-C₃₀ functional group containing at least one substituted or unsubstituted aromatic ring and R₁ is a C₁-C₆ alkyl group; and
[R₁O]₃Si—R₂ (2)
wherein, in Formula 2, R₁ is a C₁-C₆ alkyl group and R₂ is a C₁-C₆ alkyl group or a hydrogen atom.

3. The hardmask composition as claimed in claim 1, wherein the organosilane polymer is a polycondensate of hydrolysates of compounds represented by Formulae 1, 2 and 3:
[R₁O]₃SiAr (1)
wherein, in Formula 1, Ar is a C₆-C₃₀ functional group containing at least one substituted or unsubstituted aromatic ring and R₁ is a C₁-C₆ alkyl group; and
[R₁O]₃Si—R₂ (2)
wherein, in Formula 2, R₁ is a C₁-C₆ alkyl group and R₂ is a C₁-C₆ alkyl group or a hydrogen atom; and
[R₄O]₃Si—Y—Si[OR₅]₃ (3)
wherein, in Formula 3, R₄ and R₅ are each independently a C₁-C₆ alkyl group, and Y is a linking group including one of an aromatic ring, a substituted or unsubstituted linear or branched C₁-C₂₀ alkylene group, a C₁-C₂₀ alkylene group containing at least one aromatic or heterocyclic ring or having at least one urea or isocyanurate group in a backbone thereof, and a C₂-C₂₀ hydrocarbon group containing at least one multiple bond.

4. The hardmask composition as claimed in claim 1, wherein the organosilane polymer is a polycondensate of hydrolysates of compounds represented by Formulae 1, 2 and 4:
[R₁O]₃SiAr (1)
wherein, in Formula 1, Ar is a C₆-C₃₀ functional group containing at least one substituted or unsubstituted aromatic ring and R₁ is a C₁-C₆ alkyl group; and
[R₁O]₃Si—R₂ (2)
wherein, in Formula 2, R₁ is a C₁-C₆ alkyl group and R₂ is a C₁-C₆ alkyl group or a hydrogen atom; and
[R₁O]₄Si (4)
wherein, in Formula 4, R₁ is a C₁-C₆ alkyl group.

5. The hardmask composition as claimed in claim 1, wherein the organosilane polymer is a polycondensate of hydrolysates of compounds represented by Formulae 1, 2, 3 and 4:
[R₁O]₃SiAr (1)
wherein, in Formula 1, Ar is a C₆-C₃₀ functional group containing at least one substituted or unsubstituted aromatic ring and R₁ is a C₁-C₆ alkyl group; and
[R₁O]₃Si—R₂ (2)
wherein, in Formula 2, R₁ is a C₁-C₆ alkyl group and R₂ is a C₁-C₆ alkyl group or a hydrogen atom;
[R₄O]₃Si—Y—Si[OR₅]₃ (3)
wherein, in Formula 3, R₄ and R₅ are each independently a C₁-C₆ alkyl group, and Y is a linking group including one of an aromatic ring, a substituted or unsubstituted linear or branched C₁-C₂₀ alkylene group, a C₁-C₂₀ alkylene group containing at least one aromatic or heterocyclic ring or having at least one urea or isocyanurate group in a backbone thereof, and a C₂-C₂₀ hydrocarbon group containing at least one multiple bond; and
[R₁O]₄Si (4)
wherein, in Formula 4, R₁ is a C₁-C₆ alkyl group.

6. The hardmask composition as claimed in claim 1, wherein the organosilane polymer is a polycondensate of hydrolysates of compounds represented by Formulae 1, 3 and 4:
[R₁O]₃SiAr (1)
wherein, in Formula 1, Ar is a C₆-C₃₀ functional group containing at least one substituted or unsubstituted aromatic ring and R₁ is a C₁-C₆ alkyl group; and
[R₄O]₃Si—Y—Si[OR₅]₃ (3)
wherein, in Formula 3, R₄ and R₅ are each independently a C₁-C₆ alkyl group, and Y is a linking group including one of an aromatic ring, a substituted or unsubstituted linear or branched C₁-C₂₀ alkylene group, a C₁-C₂₀ alkylene group containing at least one aromatic or heterocyclic ring or having at least one urea or isocyanurate group in a backbone thereof, and a C₂-C₂₀ hydrocarbon group containing at least one multiple bond; and
[R₁O]₄Si (4)
wherein, in Formula 4, R₁ is a C₁-C₆ alkyl group.

7. The hardmask composition as claimed in claim 1, further comprising a compound including one of pyridinium p-toluenesulfonate, amidosulfobetain-16, (−)-camphor-10-sulfonic acid ammonium salt, ammonium formate, triethylammonium formate, trimethylammonium formate, tetramethylammonium formate, pyridinium formate, tetrabutylammonium formate, tetramethylammonium nitrate, tetrabutylammonium nitrate, tetrabutylammonium acetate, tetrabutylammonium azide, tetrabutylammonium benzoate, tetrabutylammonium bisulfate, tetrabutylammonium bromide, tetrabutylammonium chloride, tetrabutylammonium cyanide, tetrabutylammonium fluoride, tetrabutylammonium iodide, tetrabutylammonium sulfate, tetrabutylammonium nitrate, tetrabutylammonium nitrite, tetrabutylammonium p-toluenesulfonate, tetrabutylammonium phosphate, and mixtures thereof.

8. The hardmask composition as claimed in claim 1, wherein the stabilizer includes one of acetic anhydride, propylene glycol propyl ether, phenyltrimethoxysilane, hexamethyldisiloxane, dodecanol, and mixtures thereof.

9. The hardmask composition as claimed in claim 1, wherein the stabilizer is present in an amount of about 1 to about 30 parts by weight, based on 100 parts by weight of the organosilane polymer.

10. A process for producing a semiconductor integrated circuit device, the process comprising:
forming a carbon-based hardmask layer on a substrate,
coating a hardmask composition on the carbon-based hardmask layer to form a silicon-based hardmask layer,
forming a photoresist layer on the silicon-based hardmask layer,
exposing portions of the photoresist layer to light through a mask to form a pattern,
selectively removing exposed portions of the photoresist layer to form a patterned photoresist layer,
transferring the pattern to the silicon-based hardmask layer using the patterned photoresist layer as an etch mask to form a patterned silicon-based hardmask layer,
transferring the pattern to the carbon-based hardmask layer using the patterned silicon-based hardmask layer as an etch mask to form a patterned carbon-based hardmask layer, and
transferring the pattern to the substrate using the patterned carbon-based hardmask layer as an etch mask, wherein the hardmask composition includes:
an organosilane polymer, and
a stabilizer, the stabilizer including one of acetic anhydride, methyl acetoacetate, propionic anhydride, ethyl-2-ethylacetoacetate, butyric anhydride, ethyl-2-ethylacetoacetate, valeric anhydride, 2-methylbutyric anhydride, nonanol, decanol, undecanol, dodecanol, propylene glycol propyl ether, propylene glycol ethyl ether, propylene glycol methyl ether, propylene glycol, phenyltrimethoxysilane, diphenylhexamethoxydisiloxane, diphenylhexaethoxydisiloxane, dioctyltetramethyldisiloxane, hexamethyltrisiloxane, tetramethyldisiloxane, decamethyltetrasiloxane, dodecamethylpentasiloxane, hexamethyldisiloxane, and mixtures thereof.

11. The method as claimed in claim 10, further comprising forming an antireflective coating on the silicon-based hardmask layer prior to forming the photoresist layer on the silicon-based hardmask layer.

12. A semiconductor integrated circuit device prepared according to the method as claimed in claim 10.
